(19) United States
(12) Patent Application Publication
(10) Pub. No.: US 2006/0192299 A1
(43) Pub. Date: Aug. 31, 2006

(54) Manufacturing method for electronic device

(75) Inventor: Nobuaki Hashimoto, Suwa (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/358,894

(22) Filed: Feb. 20, 2006

(30) Foreign Application Priority Data
Feb. 25, 2005 (JP) 2005-050762
Apr. 26, 2005 (JP) 2005-127594

(51) Int. Cl. H01L 23/48

(52) U.S. Cl. 257/782; 257/E23.023; 438/118

(57) ABSTRACT

A manufacturing method for electronic device, includes: forming a first interconnection on a substrate; disposing a pedestal having a predetermined shape on the substrate; and forming a second interconnection connecting to the first interconnection, extending onto the pedestal.

### CROSS-REFERENCE TO RELATED APPLICATION

This application claims priority on Japanese Patent Application No. 2005-050762, filed Feb. 25, 2005, and Japanese Patent Application No. 2005-127594, filed Apr. 26, 2005, the contents of which are incorporated herein by reference.

### BACKGROUND

1. Technical Field

The present invention relates to a manufacturing method for electronic device.

2. Related Art

Recent years have seen an increase in research and development for using micro electro mechanical system (MEMS) techniques to manufacture super-small, super-smart electronic components (MEMS elements). Many conventional electronic components use MEMS techniques, such as inkjet heads in inkjet printers. However, in electronic components (electrical devices) manufactured using MEMS techniques and electronic components manufactured using techniques other than MEMS, due to restrictions on the area of the substrate for forming the electronic components and other reasons, there are cases when interconnections provided on the substrate cannot be connected directly to the terminals of the components which are packaged on the substrate, such as semiconductor chips.

For example, when packaging a semiconductor chip on a substrate, it is difficult to directly connect connection terminals which are exposed on side faces of the semiconductor chip to the interconnections on the substrate. Accordingly, U.S. Pat. No. 6,646,289 proposes a technique for providing interconnections which connect to the connection terminals on the side faces of the semiconductor chip and extracting them to the top face of the semiconductor chip, where they are connected to substrate interconnections provided on the substrate, enabling the connection terminals of the semiconductor chip to be connected via these interconnections to the substrate interconnections.

However, since the sections where the connection terminals exposed on the side faces of the semiconductor chip connect to the interconnections on the side faces of the semiconductor chip are linear, the connection terminals are connected to the interconnections by line contact.

Consequently, the reliability of the connection becomes problematic, since the connection section between the connection terminals and the interconnections is liable to break when a force such as external stress or bend stress is applied.

When a semiconductor chip and the like cannot be packaged directly on a substrate, one conceivable method is to provide a level difference portion such as a pedestal on the substrate and package the semiconductor chip on this a level difference portion.

### SUMMARY

An advantage of aspect of the invention is to provide a manufacturing method for electronic device which, when connecting an interconnection formed on a substrate via a level difference portion to another interconnection, prevents a connection section between these interconnections from breaking, thereby increasing the reliability of the connection, and simplifies the step of connecting the interconnections.

An aspect of the invention provides the manufacturing method for electronic device, including: forming a first interconnection on a substrate; disposing a pedestal having a predetermined shape on the substrate; and forming a second interconnection connecting to the first interconnection, extending onto the pedestal.

According to this method, the second interconnection formed on the pedestal and the first interconnection formed on the substrate are connected on the substrate, the connection section between them being achieved by face contact on the substrate. Therefore, the first interconnection and the second interconnection can be reliably conductive.

Furthermore, since the faces of first interconnection and the second interconnection are connected at the connection section, the strength of the connection section can be increased. For example, when an external force acts upon the connection section due to the electronic device being bent or dropped, the connection section can be prevented from breaking, thereby increasing the reliability of the connection. The reliability of the electronic device including this connection section can be increased.

It is preferable that the manufacturing method for electronic device of the aspect of the invention, further include: forming a sloping face at least part of a side face of the pedestal. The sloping face slopes with respect to a top face of the substrate.

According to this method, by extracting the second interconnection onto the sloping face, the second interconnection can be prevented from breaking due to bending acutely, increasing the reliability of the electronic device.

It is preferable that, in the manufacturing method for electronic device of the aspect of the invention, a sloping angle of the sloping face with respect to the top face of the substrate be an acute angle.

According to this method, the gradient between the side face of the pedestal and the top face of the substrate becomes gentle, reliably preventing the second interconnection from breaking due to acutely bending.

It is preferable that, in the manufacturing method for electronic device of the aspect of the invention, the forming of the second interconnection include: forming a seed layer on the substrate and the pedestal; coating a resist on the seed layer; forming an opening in the resist in a region on which the second interconnection is formed, and exposing the seed layer; forming the second interconnection by plating the seed layer; removing the resist; and removing the seed layer by using the second interconnection as a mask.

According to this method, since the second interconnection is formed by a process of plating, it can be formed from the first interconnection on the substrate to the pedestal in a single process. This enables the first interconnection and the second interconnection to be electrically connected reliably by face bonding. Further, since the second interconnection is formed on the first interconnection by a single process of plating, there is no need for a step of connecting the first and second interconnections, whereby the cost can be reduced. If the second interconnection is formed by a method such as sputtering, this must be done in a vacuum state, which requires a vacuum device. In contrast in this invention, since the second interconnection is formed by a process of plating, no vacuum device is required. This eliminates equipment outlay and reduces costs. Whereas, in sputtering, the shadow of the mask used in sputtering causes unevenness in the formation of the film, in the plating process the substrate and the like is immersed in a liquid solution and the second interconnection is deposited only on the seed layer, thereby enabling the plating to be deposited stably. Therefore, the second interconnection can be formed stably on a component with a complexly uneven surface.

It is preferable that, in the manufacturing method for electronic device of the aspect of the invention, the forming of the second interconnection include: forming a first layer of the second interconnection by plating the seed layer; and forming a second layer of the second interconnection by plating the first layer.

According to this method, since the second layer is laminated on the first layer, the second interconnection becomes a multilayered structure. When the second interconnection has a multilayered structure, a thickness of the second interconnection is greater than a single-layer structure. This reduces the impedance of the interconnection resistance, and increases the current.

It is preferable that, in the manufacturing method for electronic device of the aspect of the invention, the forming of the second interconnection include: performing a process of silane coupling on the substrate and the pedestal; forming a residual pattern of a silane coupling film corresponding to an interconnection pattern of the second interconnection; forming a seed layer on the residual pattern of the silane coupling film on the substrate and the pedestal; and forming the second interconnection by plating the seed layer.

According to this method, since the substrate is processed by silane coupling, the seed layer can be formed selectively in regions which have been processed by silane coupling and correspond to the second interconnection. The second interconnection can be formed only on the seed layer by plating the seed layer. Further, since the second interconnection is formed by plating, it can be formed in a single process from the first interconnection on the substrate to the pedestal, enabling the first interconnection and the second interconnection to be electrically connected reliably by face bonding. Further, since the second interconnection is formed by plating, no vacuum device is required. This eliminates equipment outlay and reduces costs. Moreover, the second interconnection can be formed stably on a component with a complexly uneven surface.

It is preferable that the manufacturing method for electronic device of the aspect of the invention, further include: preparing an electronic component having an electrode face with electrodes formed thereon; facing a top face of the pedestal and the electrode face of the electronic component; connecting the electrodes to the second interconnection extending onto the pedestal; and electrically connecting the first interconnection to the electrodes of the electronic component with the second interconnection therebetween.

According to this method, the first interconnection and the second interconnection on the substrate can be face bonded and connected in a single process of plating. Therefore, when the electrodes of the electronic component are disposed on the second interconnection, the electrodes of the electronic component can be electrically connected to the first interconnection on the substrate in a stable connection.

It is preferable that the manufacturing method for electronic device of the aspect of the invention, further include: preparing an electronic component having an electrode face with electrodes formed thereon and a back rear on an opposite side to the electrode face; facing a top face of the pedestal and the back rear of the electronic component; fixing the electronic component on the top face of the pedestal; forming an insulating section having a sloping face sloping with respect to the top face of the pedestal, on at least part of a side of the electronic component; forming the second interconnection extending from the first interconnection to the electrodes with the sloping face of the insulating section therebetween; and electrically connecting the first interconnection to the electrodes of the electronic component with the second interconnection therebetween.

According to this method, after disposing the electronic component on the pedestal, the first interconnection on the substrate can be electrically connected to the electrodes on the electrode face of the electronic component with the second interconnection therebetween. This enables the second interconnection to be formed and connected to the electronic component simultaneously, thereby simplifying the step of manufacturing the electronic device. Further, since the second interconnection is formed in a single process of plating the entire faces of the electrodes of the electronic component and the first interconnection after disposing the electronic component on the pedestal, the electrodes of the electronic component can be electrically connected to the first interconnection in a stable connection. Since the insulating section is provided on the sides of the electronic component, the second interconnection can be electrically insulated other than at terminal sections (e.g., the electrodes) of the electronic component, preventing short-circuitting at the sides of the electronic component. Moreover, since the insulating section includes the sloping face, the second interconnection can be preventing from breaking due to acutely bending by extracting it onto this sloping face. This increases the reliability of the electronic device.

It is preferable that, in the manufacturing method for electronic device of the aspect of the invention, at least additional pedestal be disposed on the pedestal, and the electronic component be disposed on the additional pedestal.

According to this method, since at least additional pedestal is disposed on the pedestal which is disposed on the substrate, the electronic device can be given a multilayered structure. As in the arrangements of the invention mentioned above, the first and second interconnections are connected on the substrate in a face contact configuration, enabling them to be made reliably conductive.

It is preferable that, in the manufacturing method for electronic device of the aspect of the invention, a sloping angle of the sloping face with respect to the top face of the pedestal be an acute angle.

According to this method, the gradient of the sloping face of the insulating section is made gentle, reliably preventing the second interconnection from breaking.

It is preferable that, in the manufacturing method for electronic device of the aspect of the invention, the electronic component include an IC chip.

According to this method, even if there are restrictions on the substrate area (e.g., if it has a narrow area), and even if the terminal section of the IC chip cannot be packaged directly on the substrate, the IC chip can be packaged by providing the stepped section between the substrate and the IC chip. Therefore, the IC chip can be packaged with high density and the electronic device can be made smaller.

### BRIEF DESCRIPTION OF THE DRAWINGS

FIG. 1 is a cross-sectional view of an electronic device in a first embodiment of the invention.

FIG. 2 is a plan view of an electronic device in the first embodiment of the invention.

FIGS. 3A to 3D are cross-sectional views of an electronic device for explaining manufacturing steps of an electronic device in the first embodiment of the invention.

FIGS. 4A to 4E are cross-sectional views of an electronic device for explaining manufacturing steps of an electronic device in the first embodiment of the invention.

FIGS. 5A to 5D are cross-sectional views of an electronic device for explaining manufacturing steps of an electronic device in a second embodiment of the invention.

FIG. 6 is a cross-sectional view of an electronic device in a third embodiment of the invention.

FIG. 7 is a plan view of an electronic device in the third embodiment of the invention.

FIGS. 8A to 8F are cross-sectional views of an electronic device for explaining manufacturing steps of an electronic device in the third embodiment of the invention.

FIG. 9 is a cross-sectional view of an electronic device in a fourth embodiment of the invention.

FIG. 10 is a cross-sectional view of another shape of an insulating section.

FIG. 11 is a cross-sectional view of another shape of an insulating section.

FIG. 12 is a cross-sectional view of another shape of an insulating section.

FIG. 13 is a cross-sectional view of another shape of an insulating section.

FIG. 14 is a cross-sectional view of another shape of an insulating section.

### DESCRIPTION OF EXEMPLARY EMBODIMENTS

### First Embodiment

Electronic Device

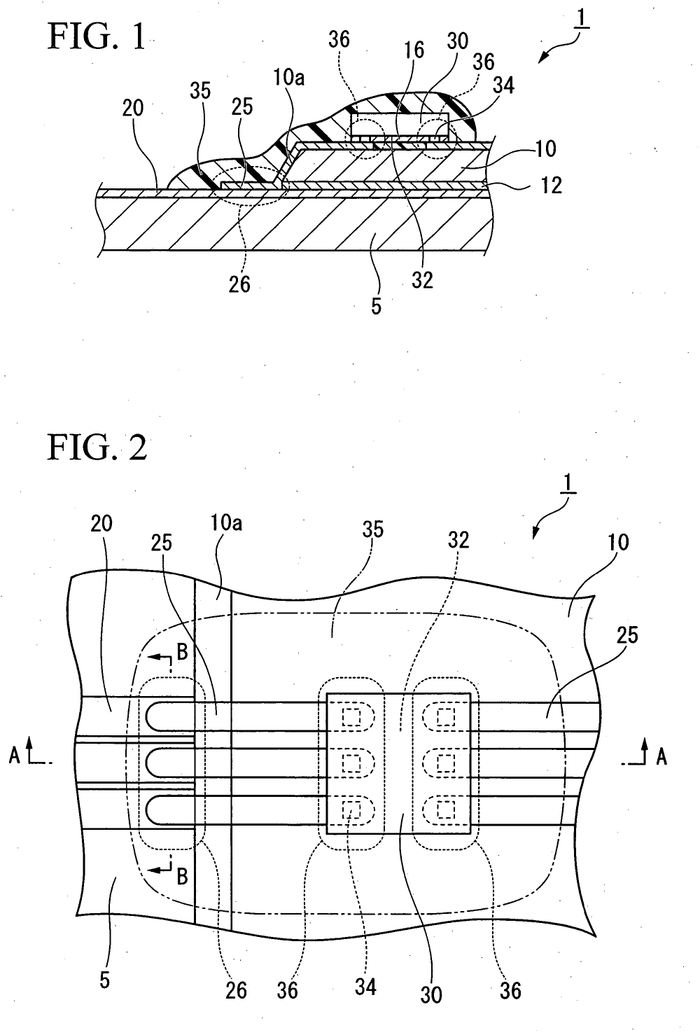

The invention will be explained in detail. FIG. 1 is a cross-sectional view of an electronic device manufactured using a manufacturing method for electronic device of the invention, being a cross-sectional view taken along the arrowed line A-A of FIG. 2. In FIG. 1, reference numeral 1 represents an electronic device of this invention. FIG. 2 is an explanatory plan view of part of the electronic device 1 (resin 35 explained later) viewed in perspective from a vertical direction.

As shown in FIG. 1, the electronic device 1 consists of a substrate 5 made from silicon (Si) or the like, and a pedestal 10 which is disposed on the substrate 5. The pedestal 10 is made from a material such as Si or ceramic, and is plate-like in shape. The pedestal 10 may include an organic substrate, an electronic component, etc. In this embodiment, the pedestal 10 is made from the same material as the substrate 5, namely Si.

When different materials are used for the substrate 5 and the pedestal 10, a difference in their thermal expansion coefficients generates stress which makes interconnections more liable to break. Accordingly, it is preferable that the material used for the pedestal 10 be the same as the material used for the substrate 5, or one which have a thermal expansion coefficient close to that of the substrate 5. In this embodiment, to reduce the effects of stress and the like due to difference in the thermal expansion coefficients, the same material is used for the pedestal 10 and the substrate 5. The height of the pedestal 10 is 400 μm. The pedestal 10 is fixed to the substrate 5 by an adhesive layer 12 consisting of an adhesive agent or the like. The pedestal 10 may be affixed to the substrate 5 by a method other than using the adhesive layer 12. For example, the pedestal 10 and the substrate 5 may be bonded together by cold bonding or interatomic bonding. The structure of the electronic device 1 of this invention is such that an electronic component such as a semiconductor chip cannot be packaged directly on the substrate 5. Accordingly, the pedestal 10 is provided such that the height of the top face of the substrate 5 differs from the height of the bottom face of the electronic component, thereby creating a level difference portion. The electronic component is then provided on top of the pedestal 10.

A first interconnection 20 of plating or the like is provided on the substrate 5 and forms an interconnection pattern. The first interconnection 20 connects to peripheral circuits (not shown) and the like. A second interconnection 25 is provided on the pedestal 10, and is electrically connected to the first interconnection 20. The first interconnection 20 and the second interconnection 25 are electrically connected on the substrate 5. The second interconnection 25 is formed by using one method from among plating, sputtering, sputter masking, chemical vapor deposition (CVD), and inkjet method. The side face of the pedestal 10 has a sloping face 10a which slopes with respect to the top face of the substrate 5. The sloping face 10a is at an acute angle to the top face of the substrate 5 (an angle greater than zero and less than 90). More specifically, when silicon with a plain orientation of (110) is used as the material for the pedestal 10 and the pedestal 10 is formed by anisotropic etching, the angle of the sloping face 10a of the pedestal 10 is 54.3 degrees with respect to the top face (horizontal plane) of the substrate 5. Incidentally in the invention, the side face of the pedestal 10 does not denote only the outer peripheral face of the pedestal 10. When an opening is provided in the top face of the pedestal 10, the side face of the pedestal 10 includes the inside faces of this opening.

The second interconnection 25, which connects to the first interconnection 20 on the substrate 5, is led over the top face of the sloping face 10a and onto the top face of the pedestal 10. The first interconnection 20 may also be provided under the adhesive layer 12. It is preferable that the angle of the sloping face 10a be small. If the film-forming conditions for sputtering and light exposure conditions for exposure make it difficult to reduce the angle of the sloping face 10a, it is acceptable for the sloping face 10a to be perpendicular. When the film of the pedestal 10 is thin, the angle of the sloping face 10a may acceptably be perpendicular (90 degrees). When the second interconnection 25 is formed by a method such as CVD, the angle of the sloping face 10a of the pedestal 10 may be obtuse (greater than 90 degrees and less than 180 degrees) with respect to the top face of the substrate 5.

An IC chip 30 (electronic component) is provided on the pedestal 10. When the electronic component disposed on the pedestal 10 is the IC chip 30 as in this embodiment, the electronic device 1 can be termed a semiconductor device. As shown in FIG. 2, a plurality of electrodes 34 is disposed on an electrode face 32 of the IC chip 30. The electrode face 32 may be quadrilateral (e.g., rectangular). For example, the plurality of electrodes 34 may be disposed along all four sides of the electrode face 32, or along only two sides. At least one of the electrodes 34 may be disposed in the center of the electrode face 32.

As shown in FIG. 1, a passivation film 16 includes at least one layer of electrically insulating film and is disposed on the electrode face 32. The passivation film 16 may acceptably be formed only from a non-resin material (e.g., SiO₂ or SiN), or it may include a layer of resin (e.g., polyimide resin) on top, or include a single resin layer. The passivation film 16 has an opening for exposing at least a part of the electrodes 34. That is, the passivation film 16 is formed such as to avoid a portion on which the electrodes 34 and the second interconnection 25 are connected. The passivation film 16 may be disposed on the sides of the electrodes 34, or may completely cover the electrode face 32.

As shown in FIG. 2, the electrodes 34 are electrically connected by contacting the second interconnection 25.

The first interconnection 20 and the second interconnection 25 are connected at a connection section 26. In this connection section 26, one face of the first interconnection 20 overlaps with one face of the second interconnection 25, and they are connected together. That is, the connection section 26 is formed on the substrate 5 by a face connection between the first interconnection 20 and the second interconnection 25.

As shown in FIG. 1, a resin 35 consists of epoxy resin, silicon resin, or the like, and covers the connection section 26 and the IC chip 30. This resin 35 protects the connection section 26 and the IC chip 30 from external collisions, moisture, and so on.

While in this embodiment, the pedestal 10 and the substrate 5 have insulating properties, when they have insufficient surface insulation or none at all, it is preferable to provide an insulating layer beforehand over an interconnection formation face on the pedestal 10 and the substrate 5. Specifically, it is preferable that an oxide film, a nitride film, a resin, or the like, be formed by an appropriate method (sputtering, spin-coating, etc.). In FIGS. 1 and 2, the electrodes 34 of the IC chip 30 are arranged facing the substrate 5. That is, FIGS. 1 and 2 depict a so-called facedown method in which the electrodes 34 of the IC chip 30 are packaged facedown on the pedestal 10. Alternatively, the electrodes 34 may be arranged facing above the substrate 5, and connected to the second interconnection 25 by a wire bonding method using wires of Au, Al, etc.

Manufacturing Method for Electronic Device

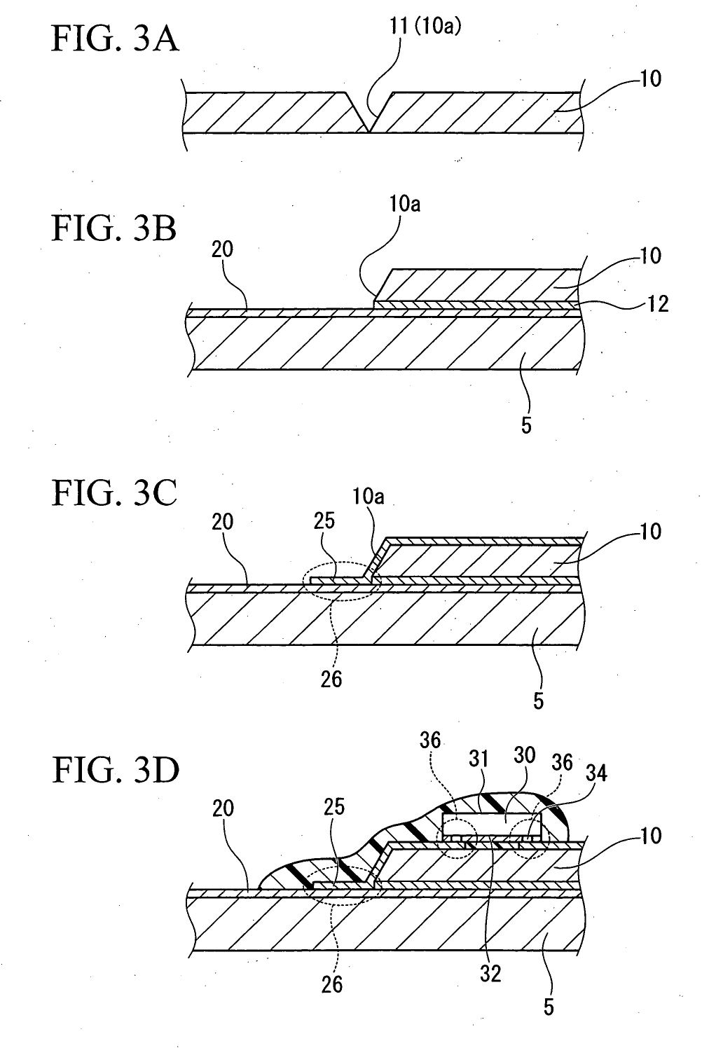

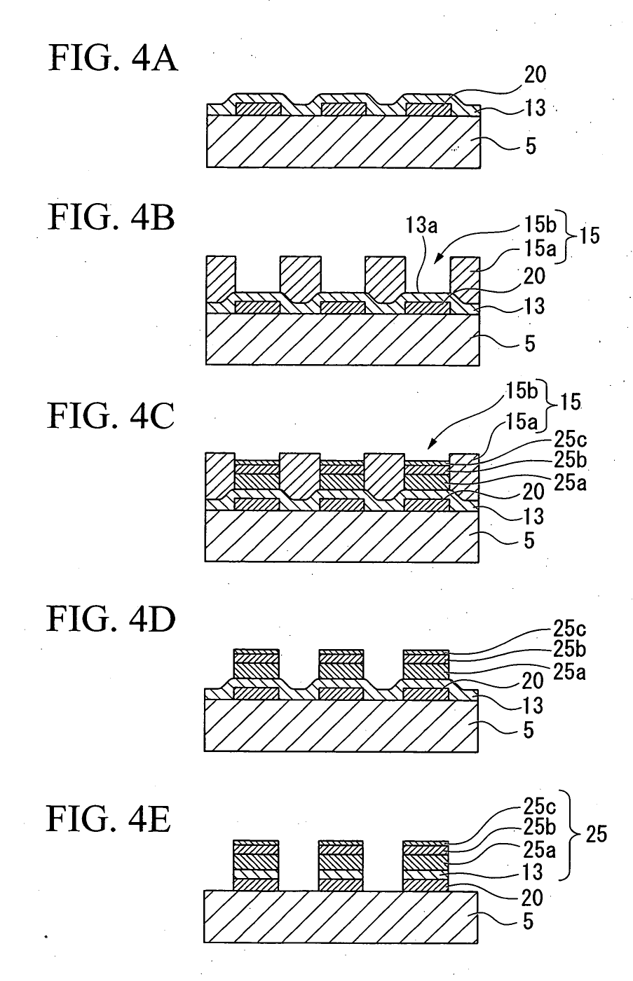

Subsequently, a method for manufacturing the electronic device 1 of this embodiment will be explained with reference to FIGS. 3A to 3D and FIGS. 4A to 4E. Firstly, as shown in FIG. 3A, a V-groove 11 is formed in the pedestal 10. As already mentioned, Si is used as the material for the pedestal 10. The formation of the V-groove 11 makes it easier to form the second interconnection 25 (explained below). The V-groove 11 can be formed by anisotropic etching, or formed mechanically using a diagonal (bevel cut) blade. After dividing (dicing) the pedestal 10 into two pieces at the bottom of the V-groove 11, the pedestal 10 having one sloping face 10a is used. A tapered face formed by contraction of resin or the like may be used instead. When the pedestal 10 has insufficient surface insulation or no insulation at all, an insulating later may be provided on an interconnection formation face on the pedestal 10. Also, the sloping face 10a at the end of the pedestal 10 is not limited to being perpendicular or an acute angle, and may be an obtuse angle instead.

As shown in FIG. 3B, the first interconnection 20 is then formed on the substrate 5 by one method from among plating, sputtering, sputter masking, CVD, and inkjet method, using a material such as Cu, Ni-p, and Au. The first interconnection 20 may be formed on the substrate 5 beforehand. The first interconnection 20 may also be formed by a method such as sputtering, or etching of a metal foil which is affixed onto the substrate 5. Prior to forming the interconnections, when the substrate 5 has insufficient surface insulation or no insulation at all, an insulating later may be provided as necessary on the substrate 5.

The substrate 5 is aligned with the position where the pedestal 10 is to be attached, and the pedestal 10 is affixed to the substrate 5 with the adhesive layer 12 in between. Instead of this adhesive layer 12, a sheet-like adhesive can be pasted onto the pedestal 10 beforehand, or the pedestal 10 may be attached using a securing method other than metal diffusion bonding using an alloy or the like, welding, adhesion by hard soldering, and such like.

Subsequently, a method for forming the second interconnection 25 on the first interconnection 20 and the pedestal 10 will be explained with reference to FIGS. 4A to 4E. FIGS. 4A to 4E are cross-sectional views taken along the line B-B of FIG. 2. As shown in FIG. 4A, the pedestal 10 and the pedestal 10 are completely covered with a seed layer 13. Palladium (Pd) is used as the material for the seed layer 13. Specifically, the electronic device 1 is immersed in a mixed solution that includes palladium and stannum, and is then processed with an acid such as hydrochloric acid. This obtains the seed layer 13 consisting only of palladium on the pedestal 10 and the first interconnection 20 of the electronic device 1. It is preferable that the faces of the first interconnection 20 and the pedestal 10 be plasma-processed before forming the seed layer 13. This increases the adhesion between the seed layer 13 and the first interconnection 20 etc. It is preferable that the seed layer 13 be formed by sputtering. As shown in FIG. 4B, a photo resist 15 is then applied over the entire seed layer 13, and is cured by heating. In the step of forming the photo resist 15, it is preferable to apply a resist material by spray-coating before forming the photo resist 15 in order to avoid unevenness in the connection section between the first interconnection 20 and the pedestal 10,

The photo resist 15 on the seed layer 13 is then patterned to a predetermined shape by photolithography. Specifically, the photo resist 15 is exposed to light using a mask which has an open pattern corresponding to the second interconnection 25. While this embodiment uses a posi-type resist, a nega-type resist could also be used.

After irradiating the open pattern of the mask, the photo resist 15 is developed. As shown in FIG. 4B, the photo resist 15 which has been exposed to light dissolves, leaving a residual part 15a of the photo resist 15 and an opening 15b which correspond to the open pattern of the mask. A seed layer 13a is exposed through the opening 15b. The opening 15b formed by removed part of the photo resist 15 becomes the region where the second interconnection 25 is formed.

In FIG. 4C, a first layer 25a of second interconnection 25 is deposited on the seed layer 13 by nonelectrolytic plating. Specifically, the electronic device 1 is immersed in a Cu plating solution for a predetermined period of time. This reduces copper ions in the solution with the palladium which constitutes the seed layer 13 as the nucleus, and separates out the copper (conductive material). Therefore, a first layer 25a is formed on the seed layer 13 at a position corresponding to the second interconnection 25. The first layer 25a extends from the first interconnection 20 on the substrate 5 to the pedestal 10, and is electrically connected to the first interconnection 20 on the substrate 5. Instead of Cu, another conductive material such as Ni-p or Au may be used as the first layer 25a.

As shown in FIG. 4C, a second layer 25b such as of Cu, Ni-p, and Au is deposited on the first layer 25a by a process of nonelectrolytic plating or electrolytic plating. The second interconnection 25 consequently has a multilayered structure. A material with excellent adhesion strength, such as Ti, W, Ti—W, Ni, and Cr, is used for the first layer 25a, and a material with low resistivity, such as Cu, Al, and Au, is used for the first layer 25a which forms the second layer. This process enables the second interconnection 25 to be made thick, reduces the impedance of interconnection resistance, and increases the current of the second interconnection 25. Preferably, the first interconnection 20 and the second interconnection 25 should be formed from mutually different materials selected from those mentioned above. If they are made from the same material, during etching and the like of the second interconnection 25, the first interconnection 20 will also be etched away. Therefore, it is preferable that different materials be used for the first interconnection 20 and the second interconnection 25.

As shown in FIG. 4C, a soldered layer 25c of Au, Sn, or the like is formed on the uppermost face of the multilayered second interconnection 25 by any type of process such as plating. This soldered layer 25c improves the connection between the second interconnection 25 and the electrodes 34 of the IC chip 30 packaged on the substrate 5. The soldered layer 25c need not be formed on the second interconnection 25. In this case, the configuration would be one wherein the second interconnection 25 does not include the soldered layer 25c.

Next, as shown in FIG. 4D, the residual part 15a of the photo resist 15 is removed.

In FIG. 4E, the seed layer 13 is etched away using the first layer 25a and the second layer 25b as masks. The portion of the seed layer 13 which is removed, is the portion below the residual part 15a of the photo resist 15. This etching process may be performed by wet etching or dry etching.

As shown in FIGS. 3C and 4E, the second interconnection 25 consequently has a multilayered structure consisting of the seed layer 13, the first layer 25a, the second layer 25b, and the soldered layer 25c, and extends from the top of the first interconnection 20 to the top of the pedestal 10.

Returning to FIG. 3D, the method for manufacturing the electronic device will be explained further.

As shown in FIG. 3D, the IC chip 30 is packaged on the second interconnection 25. In the step of packaging the IC chip 30, the electrodes 34 of the IC chip 30 are arranged facing the substrate 5 in order to connect them to the second interconnection 25. In other words, the IC chip 30 is arranged facedown. It is then packaged, and the electrodes 34 are connected to the second interconnection 25 by soldering or the like. Preferably, a resin (not shown) should be provided between the IC chip 30 and the pedestal 10 in order to increase the reliability of the connection. Instead of using soldering as the facedown packaging method in the step of packaging the IC chip 30, it is possible to use any type of method using a metal bump, such as metal bonding or resin pressure connection. Alternatively in the step of packaging the IC chip 30, the IC chip 30 may be packaged on the second interconnection 25 in a face-up arrangement (with the electrodes 34 facing upwards), and the electrodes 34 can then be connected to the second interconnection 25 by wire bonding using wires of Au, Al, etc.

After the IC chip 30 is packaged, it is molded using the resin 35 such as epoxy resin or silicon resin. The resin 35 protects the connection section 26 between the first interconnection 20 and the second interconnection 25, and the connection section 36 between the IC chip 30 and the second interconnection 25. It is preferable to use a resin with low stress as the resin 35 molded over the connection sections 26 and 36, to make it less likely to generate residual stress. Since the resin 35 covers, from the substrate 5, the connection sections 26 and 36, the second interconnection 25, and the package section of the IC chip 30, moisture-resistance in particular is made highly reliable. The electronic device 1 is manufactured by the above steps.

According to the method for manufacturing the electronic device 1 of this embodiment, since the second interconnection 25 is formed by plating, it can be formed from the first interconnection 20 on the substrate 5 to the pedestal 10 in a single process.

This enables the first interconnection 20 and the second interconnection 25 to be reliably face-bonded and electrically connected together.

The reliability of the connection section 26 between the pedestal 10 and the second interconnection 25 is thereby increased. Connection reliability is particularly increased in reliability tests such as moisture resistance cycle, bending, and dropping. Furthermore, since the first layer 25a is formed on the first interconnection 20 in a single plating process, there is no need for a separate step of connecting the first interconnection 20 and the second interconnection 25. This reduces the cost. When the second interconnection 25 is formed by, for example, sputtering, a vacuum device must conventionally be provided, since sputtering must be performed in a vacuum. In contrast according to this embodiment, since the second interconnection 25 is formed by a process of plating, no vacuum device is needed. This eliminates equipment outlay and reduces costs. Whereas the shadow of the mask used in sputtering causes unevenness in the formation of the film, in the plating process the substrate 5 is immersed in a plating solution and the second interconnection 25 is deposited only on the seed layer 13, thereby enabling the plating to be deposited stably. Therefore, a stable second interconnection can be formed on the IC chip 30 which has a complexly uneven surface.

Furthermore, since the substrate 5 is provided on the pedestal 10, and the second interconnection 25 is extracted onto the pedestal 10, the second interconnection 25 can be made conductive with the electrodes 34 at a higher position than the top face of the substrate 5. Even if the IC chip 30 cannot be directly packaged on the substrate 5 due to restrictions on the design of the substrate 5, restrictions on its area, and so on, this embodiment enables the IC chip 30 to be packaged by providing the pedestal 10 between the substrate 5 and the IC chip 30. Therefore, the IC chip 30 can be packaged with high density on the substrate 5, enabling the electronic device 1 to be made smaller.

At least part of the side face of the pedestal 10 includes the sloping face 10a which slopes at an acute angle with respect to the top face of the substrate 5. This prevents the second interconnection 25 from bending acutely at the connection section 26 on the substrate 5, and prevents the second interconnection 25 from breaking. Since the sloping face 10a slopes at an acute angle with respect to the top face of the substrate 5, the gradient of the sloping face 10a is gentle. This ensures that the second interconnection 25 is unlikely to break, reliably preventing the second interconnection 25 from breaking and increasing the reliability of the electronic device 1. When the second interconnection 25 is formed by a method such as CVD, the sloping face 10a of the pedestal 10 can be formed at an obtuse angle to the top face of the substrate 5.

The IC chip 30 is provided on the pedestal 10 and connected to the second interconnection 25. Therefore, since the electrodes 34 of the IC chip 30 provided on the pedestal 10 are connected to the second interconnection 25 on the pedestal 10, the electrodes 34 of the IC chip 30 can be made conductive with the substrate 5 via the second interconnection 25.

When providing the IC chip 30 on the substrate 5, if the IC chip 30 is provided at a higher position than the substrate 5 due to restrictions on the design of the substrate 5, restrictions on its area, and so on, this embodiment enables the electrodes 34 of the IC chip 30 to be made electrically conductive with the first interconnection 20 of the substrate 5 via the second interconnection 25 on the pedestal 10.

### Second Embodiment

Subsequently, an exemplary embodiment of an electronic device of the invention will be explained.

In the first embodiment, after forming the seed layer 13 over the entire faces of the substrate 5 and the pedestal 10, the region partitioned by the photo resist 15 (the opening 15b) is plated to form the second interconnection 25. The second embodiment differs in that a silane coupling film is disposed on the substrate 5 by a silane coupling process, a seed layer is disposed on this silane coupling film, and the second interconnection 25 is then formed by plating. Since the basic constitution of the method for forming the other patterns is the same as that of the first embodiment described above, like constituent elements are designated by like reference numerals and are not repetitiously explained.

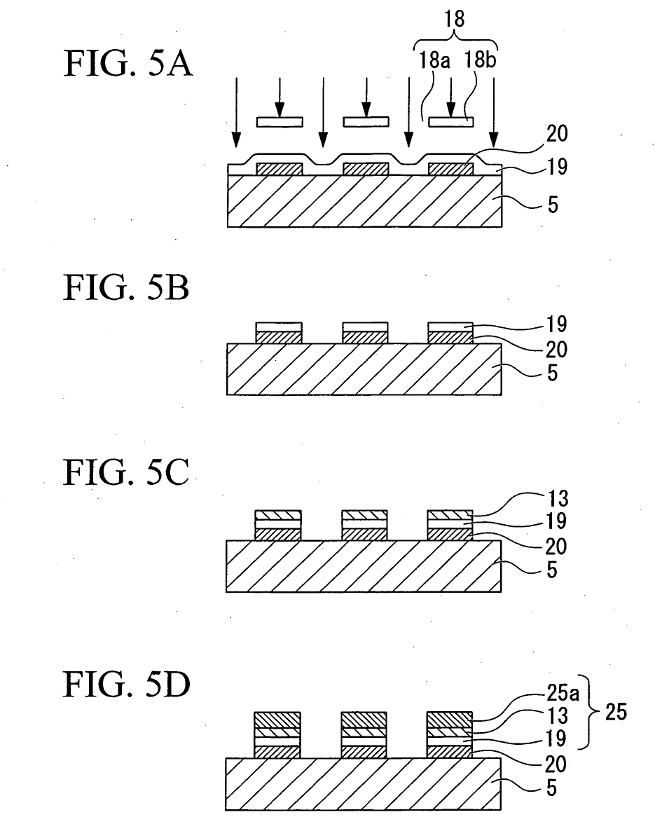

FIGS. 5A to 5D are cross-sectional views of the electronic device of FIG. 2 taken along the line B-B, and depict steps of forming the second interconnection 25 on the first interconnection 20 and the pedestal 10. In FIG. 5A, the entire faces of the pedestal 10 and the first interconnection 20 on the substrate 5 are treated with a silane coupling film. Specifically, an inkjet (IJ) method, a slit coat method, printing, or a spin coat method, is used to apply a liquid material which includes a silane coupling film such as to entirely cover the faces of the first interconnection 20 and the pedestal 10.

As shown in FIG. 5A, a mask 18 having an opening 18a is attached over the substrate 5. The open pattern of the opening 18a in the mask 18 corresponds to an unformed pattern without the second interconnection 25, and a light-shielding pattern 18b in the mask 18 corresponds to an interconnection pattern including the second interconnection 25.

Next, the silane coupling film applied to the substrate 5 is irradiated with ultraviolet rays through the mask 18. Since ultraviolet rays dissolve and remove the silane coupling film, a part of the silane coupling film which corresponds to the open pattern of the opening 18a is dissolved and removed. The part of the silane coupling film which is not irradiated by the ultraviolet rays remains on the substrate 5.

Irradiating ultraviolet rays through the open pattern of the opening 18a in the mask 18 in this manner enables the silane coupling film to be removed/retained according to a predetermined pattern.

The second interconnection 25 is thereafter formed on a residual pattern of the silane coupling film.

As shown in FIG. 5B, this obtains a residual pattern 19 of the silane coupling film corresponding to the interconnection pattern of the second interconnection 25, which extends from the first interconnection 20 on the substrate 5 to the pedestal 10, on the first interconnection 20 and the pedestal 10. While in this embodiment, the silane coupling film is dissolved and removed by irradiation of ultraviolet rays, it could alternatively be dissolved and removed by irradiation of a laser or electron rays.

In FIG. 5C, the seed layer 13 is then provided over the residual pattern 19 of the silane coupling film which is formed in the pattern formation region on the substrate 5 and the pedestal 10. As in the first embodiment, palladium (Pd) can be used as the material for the seed layer 13. To form the seed layer 13, the electronic device 1 is immersed in a mixed solution that includes palladium and stannum, and is then processed with an acid such as hydrochloric acid. This obtains the seed layer 13 consisting only of palladium on the silane coupling film.

As shown in FIG. 5D, a material for forming the second interconnection 25 is deposited on the seed layer 13 by nonelectrolytic plating to form the second interconnection 25. Specifically, the electronic device 1 is immersed in a Cu plating solution for a predetermined period of time. This reduces copper ions in the solution with the palladium which constitutes the seed layer 13 as the nucleus, separates out the copper (conductive material), and produces a first layer 25a of the second interconnection 25 on the seed layer 13 at a position corresponding to the second interconnection 25. The second interconnection 25 extends from the first interconnection 20 on the substrate 5 to the pedestal 10. In a subsequent packaging step, the second interconnection 25 is electrically connected to the electrodes 34 on the pedestal 10. Instead of Cu, another conductive material such as Ni-p or Au may be used as the second interconnection 25.

As in the first embodiment, the second layer 25b can be deposited by plating on the first layer 25a in order to increase a thickness of the second interconnection 25, thereby giving the second interconnection 25 a multilayered structure.

Any type of method such as plating can be used to provide a soldered layer 25c of Au, Sn, or the like, on the second interconnection 25.

According to this embodiment, since the substrate 5 is processed by silane coupling, the seed layer 13 can be disposed selectively only on the remaining portions of the silane coupling film. By plating the seed layer 13, it is possible to form the second interconnection 25 material only on the seed layer 13. This enables the first interconnection 20 and the second interconnection 25 to be reliably electrically connected by face bonding. Therefore, the reliability of the connection section 26 between the first interconnection 20 and the second interconnection 25 can be increased, the connection reliability being particularly increased in reliability tests such as moisture resistance cycle, bending, and dropping. Furthermore, since the second interconnection 25 is formed by plating, it can be formed in a single process from the first interconnection 20 on the substrate 5 to the pedestal 10, enabling the first interconnection 20 and the second interconnection 25 to be electrically connected by face bonding. Since the second interconnection 25 is formed by plating, no vacuum device is needed, eliminating equipment outlay and reducing costs.

### Third Embodiment

Subsequently, a third embodiment of the electronic device of the invention will be explained.

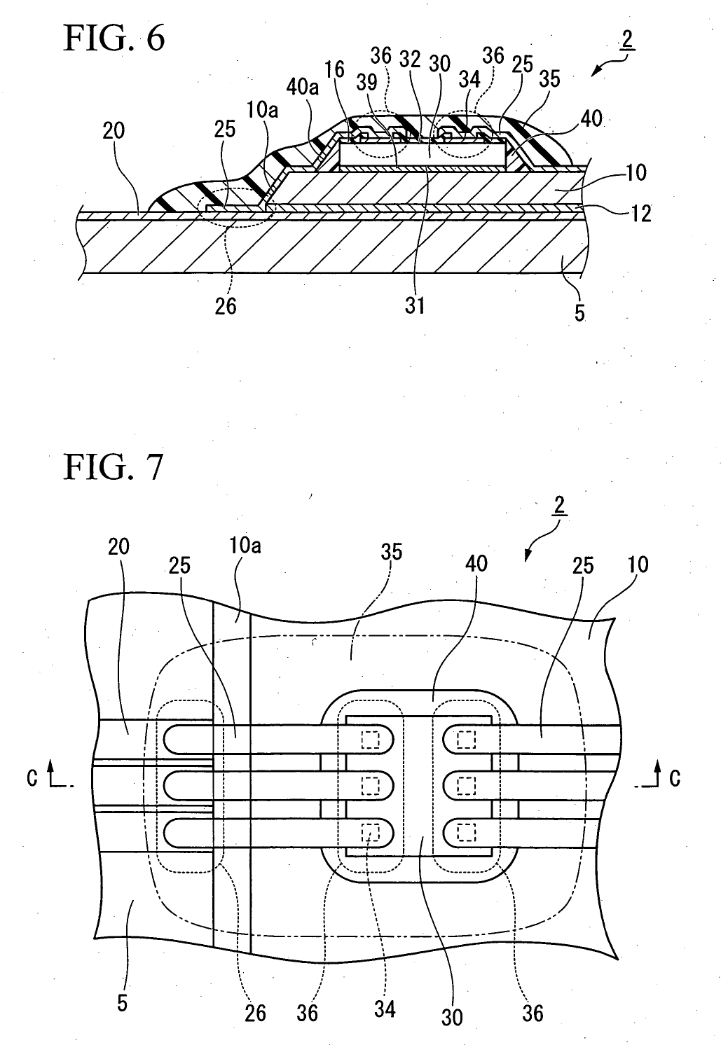

FIG. 6 and FIG. 7 are explanatory diagrams of the electronic device according to a third embodiment. FIG. 6 is a cross-sectional view taken along the arrowed line C-C of FIG. 7. In FIG. 6, reference numeral 2 represents an electronic device. FIG. 7 is an explanatory plan view of part of the electronic device 2 (resin 35 explained later) viewed in perspective from a vertical direction. Like constituent elements to those of the first embodiment are designated by like reference numerals and are not repetitiously explained.

In the electronic device 2 of this embodiment, the second interconnection 25 of the electronic device 1 of the first embodiment is connected such as to cover the electrodes 34. The electrodes 34 are formed on the electrode face 32 of the IC chip 30, and consist of a metal such as Al. An insulating section (explained below) is formed around the periphery of the IC chip 30. To prevent oxidization of the electrodes 34, it is preferable that the electrodes 34 be entirely covered by plating of Ni or the like. It is preferable that bumps of a metal such as Al, Ni—Cr, Cu, Ni, Au, and Ag, be formed on the electrodes 34, achieving conduction between the second interconnection 25 and the electrodes 34. The plating and the bumps are formed by a process of nonelectrolytic plating. The configuration of the electronic device 2 is otherwise identical to that of the electronic device 1 of the first embodiment. As shown in FIG. 6, the electronic device 2 includes the substrate 5, and the pedestal 10 which is provided on the substrate 5. The pedestal 10 is fixed to the substrate 5 by the adhesive layer 12. The first interconnection 20 is formed on the substrate 5 by a method such as plating, sputtering, sputter masking, CVD, and inkjet method.

The side face of the pedestal 10 has a sloping face 10a which slopes with respect to the top face of the substrate 5. The sloping face 10a is at an acute angle to the top face of the substrate 5. The IC chip 30 is arranged on top of the pedestal 10. A back face 31 of the IC chip 30 is affixed onto the pedestal 10 with an adhesive layer 39 therebetween. An insulating section 40 covers the side faces of the IC chip 30. This insulating section 40 has a sloping face 40a which slopes toward the outer side. At this sloping face 40a, the thickness of the insulating section 40 gradually decreases from the insulating section 40 toward the pedestal 10. Therefore, the thickest part of the insulating section 40 contacts the IC chip 30, and the thinnest part of the insulating section 40 is most distant from the IC chip 30.

The insulating section 40 is formed from a material having electrical insulating (e.g., resin). The insulating section 40 may be formed from a different material than the adhesive layer 39, or from the same material. As in this embodiment, the insulating section 40 may contact the side faces of the IC chip 30. That is, there need not be a gap between the insulating section 40 and the IC chip 30. In the example of FIG. 6, the height of the insulating section 40 does not exceed that of the IC chip 30.

As shown in FIG. 7, the second interconnection 25 of the electronic device 2 is formed by sputtering and photolithography, as in the electronic device 1. The second interconnection 25 connects to the first interconnection 20 on the substrate 5, and is extracted onto the sloping face 10a of FIG. 6 and onto the pedestal 10. Moreover, the second interconnection 25 is extracted onto the sloping face 40a of the insulating section 40 and connected to the electrodes 34 formed on the electrode face 32 of the IC chip 30. Therefore, at the connection section 26 between the first interconnection 20 and the second interconnection 25, one face of the first interconnection 20 overlaps with one face of the second interconnection 25, and they are connected together. That is, the connection section 26 is formed on the substrate 5 by a face connection between the first interconnection 20 and the second interconnection 25. Similarly, at the connection section 36 between the electrodes 34 and the second interconnection 25, one face of the first interconnection 20 overlaps with the electrodes 34, and they are connected together. That is, the connection section 36 is formed on the substrate 5 by a face connection between the second interconnection 25 and the electrodes 34.

The resin 35 covers the IC chip 30, molding and protecting the connection section 26 between the first interconnection 20 and the second interconnection 25, and the connection section 36 between the IC chip 30 and the second interconnection 25. In this arrangement, the resin 35 covers, from the substrate 5, the connection sections 26 and 36, the second interconnection 25, and the package section of the IC chip 30, and thereby particularly increases the reliability of moisture resistance.

Manufacturing Method for Electronic Device

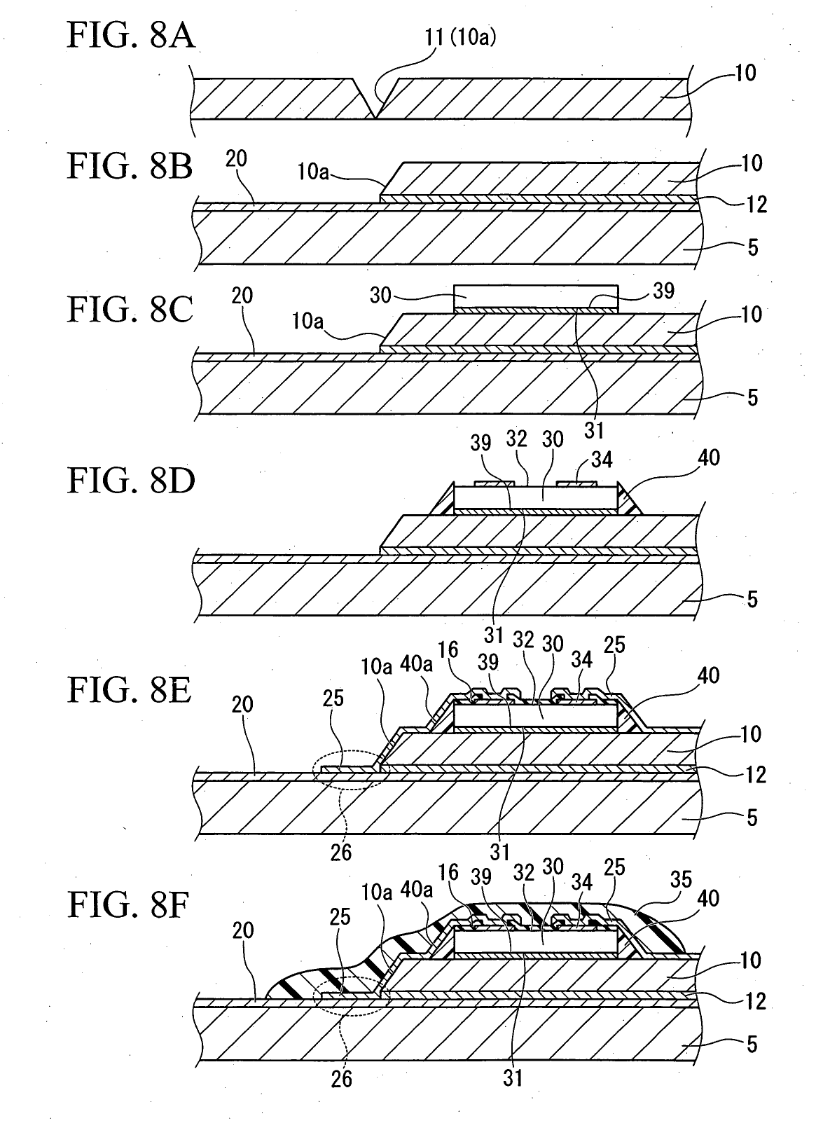

Subsequently, a method for manufacturing the electronic device 2 of this embodiment will be explained with reference to FIGS. 8A to 8F. In this embodiment, the step of manufacturing the pedestal 10 shown in FIG. 8A, the step of affixing the pedestal 10 to the substrate 5 shown in FIG. 8B, and the other steps are identical to the steps of the first embodiment and will not be repetitiously explained.

Firstly, in FIGS. 8A and 8B, the sloping face 10a is formed on the pedestal 10, and the pedestal 10 is affixed onto the substrate 5. In FIG. 8C, the IC chip 30 is then affixed onto the pedestal 10 using the adhesive layer 39. FIG. 8C is a schematic representation of the IC chip 30.

As shown in FIG. 8D, the insulating section 40 is then formed on the side faces of the IC chip 30. In the step of forming the insulating section 40, the sloping face 40a is formed on the insulating section 40 such as to slopes toward the bottom face of the pedestal 10 toward the outer side. The insulating section 40 may be formed from a resin such as polyimide resin, silicon-modified polyimide resin, epoxy resin, silicon-modified epoxy resin, benzocyclobutene (BCB), and polybenzoxazole (PBO). The insulating section 40 can be formed by potting of liquefied resin, or by firmly fixing a dry film. The insulating section 40 can also be formed by providing a material which is different to that of the adhesive agent which forms the expansion processor 39, or the same material. It is preferable that the faces of the electrodes 34 on the IC chip 30 be entirely covered by plating of Ni or the like. This prevents formation of an oxidization film on the electrodes 34. It is preferable that bumps consisting of a metal material such as Al, Ni—Cr, Cu, Ni, Au, and Ag, be formed on the electrodes 34 to achieve electrical conduction between the second interconnection 25 and the electrodes 34.

In FIG. 8E, the second interconnection 25 which connects to the first interconnection 20 is formed on the substrate 5. Since the second interconnection 25 is connected to the top face of the IC chip 30, i.e., to the electrodes 34 on the electrode face 32, the second interconnection 25 obtains conductivity between the first interconnection 20 and the electrodes 34.

The second interconnection 25 is formed using a method such as plating, sputtering, sputter masking, CVD, and inkjet method. Specifically, as in the formation method of the first embodiment, the seed layer 13, which corresponds to the interconnection pattern of the second interconnection 25, is formed on the top faces of the first interconnection 20, the pedestal 10, the sloping face 40a of the insulating section 40, and the IC chip 30. The second interconnection 25 is then deposited on the seed layer 13 by a process of nonelectrolytic plating. Using the second interconnection 25 as a mask, the seed layer 13 is removed by etching to form the second interconnection 25. Consequently, the second interconnection 25 can be formed such that it extends from the top of the first interconnection 20, via the pedestal 10 and the sloping face 40a of the insulating section 40, to the electrodes 34 on the top face of the IC chip 30. As shown in FIG. 7, the second interconnection 25 connects to the first interconnection 20 on the substrate 5 via face-contact. The second interconnection 25 also face-contacts the electrodes 34 of the IC chip 30. It is preferable that bumps or a barrier metal be provided on the top face of the electrodes 34 of the IC chip 30 to suppress oxidization.

As shown in FIG. 8F, the connection section 26 between the first interconnection 20 and the second interconnection 25, and the IC chip 30, are covered by the resin 35. The electronic device 2 of the invention is manufactured by the above steps.

According to the manufacturing method for the electronic device 2 of this embodiment, as in the electronic device 1 of the first embodiment described above, the second interconnection 25 can be arranged such that it overlaps the first interconnection 20, achieving reliable conductivity between the first interconnection 20 and the second interconnection 25. At the connection section 26, the first interconnection 20 and the second interconnection 25 can be connected on the substrate 5 by face contact. This increases the strength of the connection section 26 between the first interconnection 20 and the second interconnection 25, increases the reliability of the connection in reliability tests such as moisture resistance cycle, bending, and dropping, and prevents breakage by increasing the strength of the connection section.

Since at least part of the side face of the pedestal 10 includes the sloping face 10a which slopes at an acute angle with respect to the top face of the substrate 5, it is possible to prevent the second interconnection 25 from bending acutely at the connection section 26 with the pedestal 10 and the substrate 5. In other words the second interconnection 25 can be prevented from breaking, thereby increasing the reliability of the electronic device 2.

Even if the pedestal 10 is not used and the IC chip 30 with a sloping face is packaged directly onto the substrate 5, the second interconnection 25 can be prevented from breaking in the same manner as the pedestal 10, thereby increasing the reliability of the electronic device.

Since the IC chip 30 is provided on the pedestal 10 and the electrodes 34 of the IC chip 30 are connected to the second interconnection 25, the electrodes 34 become conductive with the first interconnection 20 on the substrate 5 via the second interconnection 25.

The second interconnection 25 connects to the electrodes 34 formed on the electrode face 32 of the IC chip 30. The second interconnection 25 is connected to the electrodes 34 after arranging the IC chip 30 on the pedestal 10. The second interconnection 25 can therefore be formed and connected to the electrodes 34 simultaneously, greatly simplifying the step of manufacturing the electronic device 2. By a process of photolithography, a photo resist can be patterned to match the second interconnection 25, which can thus be formed with a very fine pitch. According to this manufacturing method of the electronic device 2, the connection between the first interconnection 20 and the second interconnection 25 at the connection section 26 on the substrate 5 is planar rather than linear. This increases the strength of the connection section 26.

For example, when an external force acts upon the connection section 26 due to the electronic device 2 being bent or dropped, this invention prevents the connection section 26 from breaking and thereby increases the reliability of the connection. Furthermore, since the second interconnection 25 can be formed simultaneously to connecting it to the first interconnection 20, the number of manufacturing steps can be reduced. In conventional electronic devices, when the structure includes a great many connections, the number of steps for forming interconnection between the first interconnection and the electrodes also increases. In contrast in this embodiment, even if the structure includes a great number of connections, the number of steps can be reduced since only one step is needed to form the second interconnection 25.

Since the second interconnection 25 is extracted onto the sloping face 10a on the side face of the pedestal 10, it can be prevented from breaking due to bending acutely at the connection section 26 between the pedestal 10 and the substrate 5.

After forming the IC chip 30 on the pedestal 10, the second interconnection 25 is formed on the electrodes 34 on the back face 31 of the IC chip 30. Therefore, the second interconnection 25 can be manufactured and connected to the IC chip 30 simultaneously, simplifying the step of manufacturing the electronic device 2.

The insulating section 40 provided around the sides of the IC chip 30 insulates the parts other than the electrodes 34 on the electrode face 32 of the IC chip 30. This prevents the second interconnection 25 on the insulating section 40 from short-circuitting between the second interconnection 25 and the side face of the IC chip 30. Since the top face of the IC chip 30 is covered by the passivation film 16, a short-circuitting between the IC chip 30 and the second interconnection 25 can be prevented. Since the insulating section 40 includes the sloping face 40a, this sloping face 40a can be used to prevent the second interconnection 25 from acutely bending when extracting the second interconnection 25 to the electrodes 34 of the IC chip 30. This prevents the second interconnection 25 from breaking. Since the sloping face 40a slopes at an acute angle with respect to the top face of the substrate 5, the gradient of the second interconnection 25 with respect to the pedestal 10 becomes gentle, preventing the second interconnection 25 from breaking.

Incidentally in this embodiment, the second interconnection 25 can be formed on the sloping face 40a by sputtering or the like, in the same manner as when the second interconnection 25 is formed on the sloping face 10a of the pedestal 10. In this case, since the sloping face 40a formed on the insulating section 40 faces the sputtering target direction, the sputtering cohesion is enhanced. Therefore, the thickness of the second interconnection 25 can be kept stable. By providing the sloping face 40a, it is possible to coat the entire sloping face 40a with the photo resist for forming the second interconnection 25, enabling the entire photo resist to be stably exposed. This enables the second interconnection 25 to be formed easily. Therefore, the second interconnection 25 can be prevented from breaking between the insulating section 40 and the pedestal 10, and enables the second interconnection 25 to reliably connect the first interconnection 20 to the electrodes 34. Similarly, when the second interconnection 25 is formed by sputtering, sputter masking, CVD, or inkjet method, the second interconnection 25 can be prevented from breaking between the insulating section 40 and the pedestal 10, enabling the second interconnection 25 to reliably connect the first interconnection 20 to the electrodes 34.

### Fourth Embodiment

Subsequently, a fourth embodiment of the electronic device according to the invention will be explained.

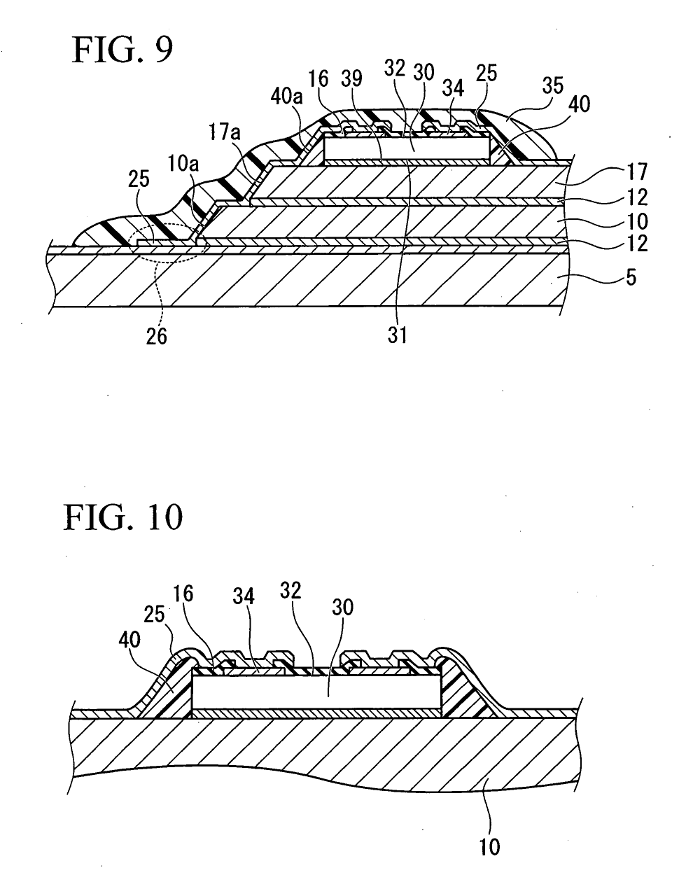

FIG. 9 is a schematic cross-sectional view of the electronic device in a fourth embodiment. Like constituent elements to those of the first embodiment are designated by like reference numerals, and are not repetitiously explained.

As shown in FIG. 9, in this embodiment, another pedestal (second pedestal) 17 is disposed on the pedestal (first pedestal) 10 on the substrate 5. That is, the pedestals 10 and 17 are arranged in a two-level structure on the substrate 5. The number of levels of pedestals disposed on the substrate 5 is not limited to two, it being possible to dispose a great many levels. The pedestal (additional pedestal) 17 can be affixed onto the pedestal 10 by using the adhesive layer 12 consisting of an adhesive agent or the like, or by a method which does not use an adhesive, such as cold bonding or interatomic bonding. The side face of the pedestal 17 has a sloping face 17a which slopes at an acute angle with respect to the substrate 5, as in the first embodiment.

The second interconnection 25 is formed by the plating process described in the first and the second embodiments. As shown in FIG. 7, the second interconnection 25 is extracted from the first interconnection 20, along the sloping face 10a of the pedestal 10, the sloping face 17a of the pedestal 17, and the sloping face 40a of the insulating section 40, onto the top face (electrode face 32) of the IC chip 30, and connects to the electrodes 34 on the top face (electrode face 32) of the IC chip 30. Thus the first interconnection 20 and the electrodes 34 of the IC chip 30 are electrically connected via the second interconnection 25. The second interconnection 25 can be formed by sputtering, sputter masking, CVD, or inject method. According to this embodiment, the same advantageous effects are achieved as in the embodiments described above.

That is, even when a plurality of the pedestals 10 and 17 are laminated on the substrate 5, since the second interconnection 25 is formed by a process of plating or the like, the second interconnection 25 can be securely bonded to the first interconnection 20 at the connection section 26, and electrically connected thereto.

While in the third embodiment and the fourth embodiment, the insulating section 40 around the IC chip 30 has the sloping face 40a, the shape of the insulating section 40 could be any of the following.

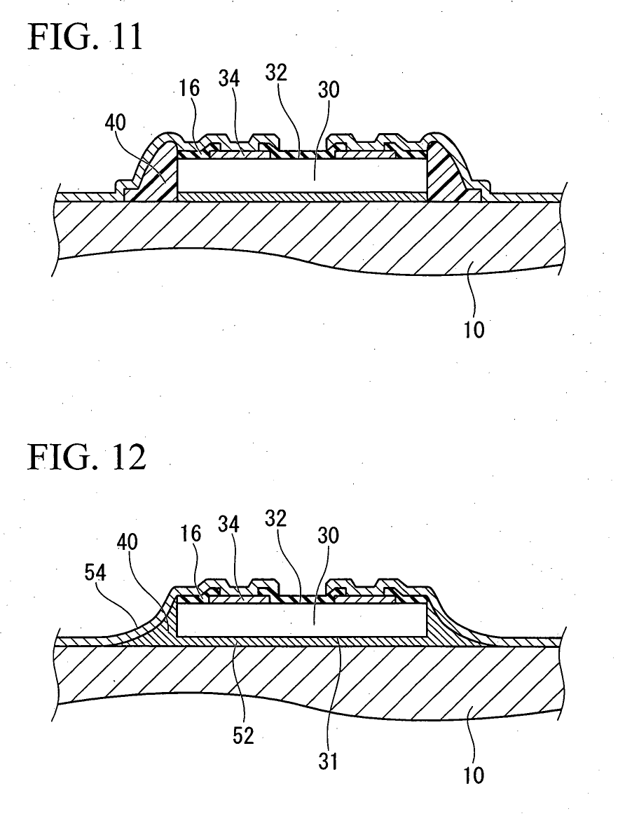

As for example shown in FIG. 10, the insulating section 40 can be formed such that part of it rises onto the electrode face 32 (specifically the passivation film 16) of the IC chip 30. The insulating section 40 consequently abuts to the IC chip 30 and rises up from the electrode face 32, and includes a convex section which rises onto the electrode face 32. The insulating section 40 must be prevented from covering the electrodes 34 to ensure that they are reliably exposed. Accordingly, it is preferable that the insulating section 40 be formed at a distance from the electrodes 34 (at a position further to the inner peripheral side of the IC chip 30 than the electrodes 34). Alternatively, the insulating section 40 may abut to the part of the passivation film 16 exposed by the electrodes 34. Preferably in this case, the second interconnection 25 should not rise onto the passivation film 16, which has low adhesion to the second interconnection 25. When there is poor adhesion between the electrodes 34 or the IC chip 30 and the passivation film 16 which covers them, a resin layer may be provided on the passivation film 16 to increase the adhesion. In the structure shown in FIG. 10, the configuration is otherwise the same as that of the IC chip 30 shown in FIG. 1. In FIG. 11, no part of the insulating section 40 rises up (overlaps) onto the electrode face 32 of the IC chip 30. The insulating section 40 has a convex section which abuts to the IC chip 30 and rises higher than the electrode face 32. The insulating section 40 includes a stair-like level difference portion near the connection section with the pedestal 10 on the opposite side to the IC chip 30. The configuration in FIG. 11 is otherwise the same as the IC chip 30 shown in FIG. 1.

As shown in FIG. 12, the insulating section 40 may be formed together with an adhesive layer 52. The adhesive layer 52 is made from the same material as the insulating section 40. One example of a method for forming the insulating section 40 and the adhesive layer 52 is to affix the back face 31 of the IC chip 30 to the adhesive layer 52, and then form the insulating section 40 on the sides of the IC chip 30. It is also possible to provide an insulating adhesive agent between the pedestal 10 and the IC chip 30, and apply a pressing force between them so that the adhesive agent flows alongside the IC chip 30 and is pressed against the IC chip 30, thereby forming the insulating section 40 and the adhesive layer 52. A sloping face 54 of the insulating section 40 is concave (e.g., a concave face which is curved when viewed in cross-section at a perpendicular to the electrode face 32). The configuration in FIG. 12 is otherwise the same as the IC chip 30 shown in FIG. 1.

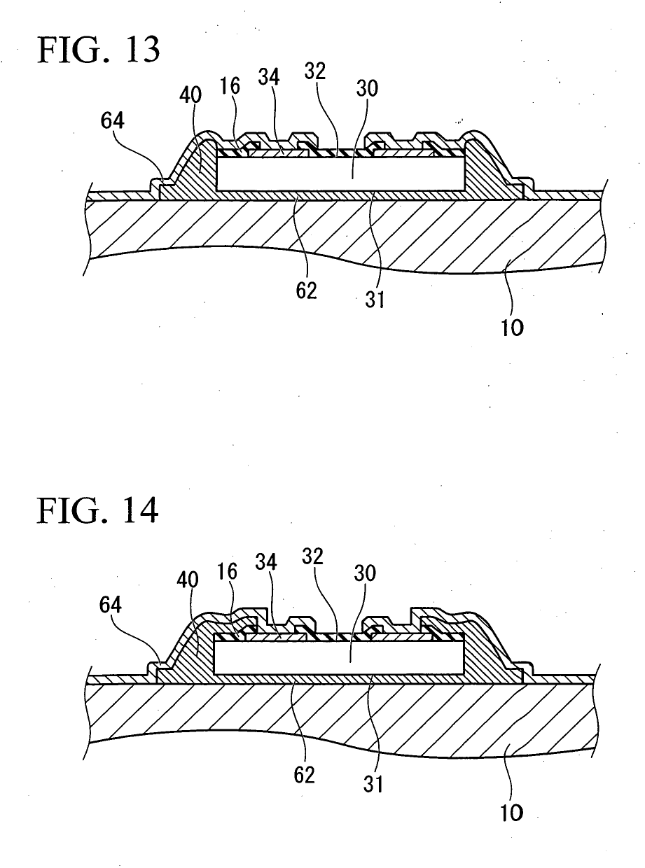

As shown in FIG. 13, the insulating section 40 can be formed together with an adhesive layer 62. The adhesive layer 62 is made from the same material as the insulating section 40. One example of a method for forming the insulating section 40 and the adhesive layer 62 is to affix the back face 31 of the IC chip 30 to the adhesive layer 62, and then form the insulating section 40 on the sides of the IC chip 30. It is also possible to provide an insulating adhesive agent between the pedestal 10 and the IC chip 30, and apply a pressing force between them so that the adhesive agent flows alongside the IC chip 30 and is pressed against the IC chip 30, thereby forming the insulating section 40 and the adhesive layer 62. A sloping face 64 of the insulating section 40 is concave (e.g., a concave face which is curved when viewed in cross-section at a perpendicular to the electrode face 32). The configuration in FIG. 13 is otherwise the same as the IC chip 30 shown in FIG. 1.

As shown in FIG. 14, part of the insulating section 40 may rise onto the passivation film 16 which is provided on the edge of the IC chip 30. The insulating section 40 does not rise onto the electrodes 34. Incidentally, the structure of the electronic device of FIG. 14 can also be applied in the electronic devices of FIG. 11 to FIG. 13.

The invention is not limited to the embodiments described above and can be modified in various ways. In the above embodiments, the second interconnection 25 is formed on the outer peripheral face of the pedestal 10. The invention is not limited to this. An opening may be provided in the top face of the pedestal 10, and an inner face formed in the opening. By extracting the second interconnection 25 onto the inner face (side face) of the opening, the interconnection in this opening can be connected to the second interconnection 25 and made conductive therewith. While these embodiments use the IC chip 30 as the electronic component formed on the pedestal 10, a passive component (a resistor, a capacitor, an inductor, etc.) can be used instead of the IC chip 30. A plurality of different types of these components may be provided. While in these embodiments, the side face of the IC chip 30 is perpendicular to the substrate 5, the pedestal 10, and so on, the IC chip 30 may include a sloping face which slopes with respect to the top faces of the substrate 5 and the pedestal 10. In this case, the IC chip 30 is formed by using a diagonal (bevel cut) blade to mechanically cut (dice) a silicon wafer. Since the side face of the IC chip 30 thus becomes a sloping face, the insulating section 40 can easily be formed on the sloping face of the IC chip 30.

While preferred embodiments of the invention have been described and illustrated above, it should be understood that these are exemplary of the invention and are not to be considered as limiting. Additions, omissions, substitutions, and other modifications can be made without departing from the spirit or scope of the invention. Accordingly, the invention is not to be considered as being limited by the foregoing description, and is only limited by the scope of the appended claims.

What is claimed is:

1. A manufacturing method for electronic device, comprising:
forming a first interconnection on a substrate;
disposing a pedestal having a predetermined shape on the substrate; and
forming a second interconnection connecting to the first interconnection, extending onto the pedestal.

2. A manufacturing method for electronic device according to claim 1, further comprising:
forming a sloping face at least part of a side face of the pedestal, wherein the sloping face slopes with respect to a top face of the substrate.

3. A manufacturing method for electronic device according to claim 2, wherein a sloping angle of the sloping face with respect to the top face of the substrate is an acute angle.

4. A manufacturing method for electronic device according to claim 1, wherein the forming of the second interconnection includes:
forming a seed layer on the substrate and the pedestal;
coating a resist on the seed layer;
forming an opening in the resist in a region on which the second interconnection is formed, and exposing the seed layer;
forming the second interconnection by plating the seed layer;
removing the resist; and
removing the seed layer by using the second interconnection as a mask.

5. A manufacturing method for electronic device according to claim 4, wherein the forming of the second interconnection includes:
forming a first layer of the second interconnection by plating the seed layer; and
forming a second layer of the second interconnection by plating the first layer.

6. A manufacturing method for electronic device according to claim 1, wherein the forming of the second interconnection includes:
performing a process of silane coupling on the substrate and the pedestal;
forming a residual pattern of a silane coupling film corresponding to an interconnection pattern of the second interconnection;
forming a seed layer on the residual pattern of the silane coupling film on the substrate and the pedestal; and
forming the second interconnection by plating the seed layer.

7. A manufacturing method for electronic device according to claim 1, further comprising:
preparing an electronic component having an electrode face with electrodes formed thereon;
facing a top face of the pedestal and the electrode face of the electronic component;
connecting the electrodes to the second interconnection extending onto the pedestal; and
electrically connecting the first interconnection to the electrodes of the electronic component with the second interconnection therebetween.

8. A manufacturing method for electronic device according to claim 7, wherein at least additional pedestal is disposed on the pedestal, and the electronic component is disposed on the additional pedestal.

9. A manufacturing method for electronic device according to claim 7, wherein the electronic component includes an IC chip.

10. A manufacturing method for electronic device according to claim 1, further comprising:
preparing an electronic component having an electrode face with electrodes formed thereon and a back rear on an opposite side to the electrode face;
facing a top face of the pedestal and the back rear of the electronic component;
fixing the electronic component on the top face of the pedestal;
forming an insulating section having a sloping face sloping with respect to the top face of the pedestal, on at least part of a side of the electronic component;
forming the second interconnection extending from the first interconnection to the electrodes with the sloping face of the insulating section therebetween; and
electrically connecting the first interconnection to the electrodes of the electronic component with the second interconnection therebetween.

11. A manufacturing method for electronic device according to claim 10, wherein at least additional pedestal is disposed on the pedestal, and the electronic component is disposed on the additional pedestal.

12. A manufacturing method for electronic device according to claim 10, wherein a sloping angle of the sloping face with respect to the top face of the pedestal is an acute angle.

13. A manufacturing method for electronic device according to claim 10, wherein the electronic component includes an IC chip.
